(19) United States
(12) Patent Application Publication
(10) Pub. No.: US 2017/0236566 A1
(43) Pub. Date: Aug. 17, 2017

(54) DATA TRANSFER FOR MULTI-LOADED SOURCE SYNCHROUS SIGNAL GROUPS

(71) Applicant: Intel Corporation, Santa Clara, CA (US)

(72) Inventors: Pooja Nukala, Portland, OR (US); Christopher Mozak, Beaverton, OR (US); Kristina D. Morgan, Hillsboro, OR (US); Rebecca Loop, Hillsboro, OR (US)

(73) Assignee: Intel Corporation, Santa Clara, CA (US)

(21) Appl. No.: 15/046,384

(22) Filed: Feb. 17, 2016

(51) Int. Cl. G11C 7/10; G06F 13/16

(52) U.S. Cl. CPC G11C 7/1072; G06F 13/1689; G06F 13/1673

(57) ABSTRACT

Memory devices, systems, and methods that maximize command and address (CA) signal group rate with minimized margin degradation across a channel and associated operating modes are disclosed and described. In one example, the operating mode can be 1 bit per 1.5 clock cycles.

### BACKGROUND

Computer devices and systems have become integral to the lives of many and include all kinds of uses from social media to intensive computational data analysis. Such devices and systems can include tablets, laptops, desktop computers, network servers, and the like. Memory subsystems play an important role in the implementation of such devices and systems, and are one of the key factors affecting performance.

One type of volatile memory used in many computer devices and systems is dynamic random access memory (DRAM). DRAM stores data bits in capacitors within an integrated circuit. Because of the capacitors' tendency to slowly discharge, they require periodic refreshing. Another form of DRAM, known as synchronous DRAM (SDRAM), is essentially DRAM with a synchronous interface that synchronizes to the system bus.

Every computer contains one or more internal clocks that regulate the rate at which instructions are executed and synchronizes all the various computer components. For example, the central processing unit (CPU) requires a fixed number of clock ticks (e.g. clock cycles) to execute each instruction. Other components such as expansion buses can also have a clock. The Joint Electron Device Engineering Council (JEDEC) defines various Double data rate (DDR) specifications defining memory interface and device operations on both the rising and falling edges of a system clock signal. This gives DDR-compliant devices the capability to move information, such as command and address signals, in some cases, at nearly twice the rate than previously possible.

### BRIEF DESCRIPTION OF THE DRAWINGS

FIG. 1 shows a comparative timing diagram of various command/address signal group modes, including a clock, 1N mode, and 2N mode;

FIG. 2 shows a comparative timing diagram of various command/address signal group modes, including a clock, 1N mode, 2N mode, and 1.5N mode;

FIG. 3 shows a schematic diagram of an exemplary memory device;

FIG. 4 shows an exemplary method of increasing throughput of a command/address bus;

FIG. 5 shows an exemplary memory device;

FIG. 6 is a schematic view of an exemplary computing system;

FIG. 7a is a graphical representation of simulated eye diagram data.

FIG. 7b is a graphical representation of simulated eye diagram data.

FIG. 7c is a graphical representation of simulated eye diagram data.

### DESCRIPTION OF EMBODIMENTS

Although the following detailed description contains many specifics for the purpose of illustration, a person of ordinary skill in the art will appreciate that many variations and alterations to the following details can be made and are considered included herein.

Accordingly, the following embodiments are set forth without any loss of generality to, and without imposing limitations upon, any claims set forth. It is also to be understood that the terminology used herein is for describing particular embodiments only, and is not intended to be limiting. Unless defined otherwise, all technical and scientific terms used herein have the same meaning as commonly understood by one of ordinary skill in the art to which this disclosure belongs.

In this application, “comprises,” “comprising,” “containing” and “having” and the like can have the meaning ascribed to them in U.S. Patent law and can mean “includes,” “including,” and the like, and are generally interpreted to be open ended terms. The terms “consisting of or” consists of are closed terms, and include only the components, structures, steps, or the like specifically listed in conjunction with such terms, as well as that which is in accordance with U.S. Patent law. “Consisting essentially of or” consists essentially of have the meaning generally ascribed to them by U.S. Patent law. In particular, such terms are generally closed terms, with the exception of allowing inclusion of additional items, materials, components, steps, or elements, that do not materially affect the basic and novel characteristics or function of the item(s) used in connection therewith. For example, trace elements present in a composition, but not affecting the compositions nature or characteristics would be permissible if present under the “consisting essentially of” language, even though not expressly recited in a list of items following such terminology. When using an open ended term in this specification, like “comprising” or “including,” it is understood that direct support should be afforded also to “consisting essentially of” language as well as “consisting of” language as if stated explicitly and vice versa.

“The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments described herein are, for example, capable of operation in other orientations than those illustrated or otherwise described herein.

As used herein, “enhanced,” “improved,” “performance-enhanced,” “upgraded,” and the like, when used in connection with the description of a device or process, refers to a characteristic of the device or process that provides measurably better form or function as compared to previously known devices or processes. This applies both to the form and function of individual components in a device or process, as well as to such devices or processes as a whole.

As used herein, “coupled” refers to a relationship of physical connection or attachment between one item and another item, and includes relationships of either direct or indirect connection or attachment. Any number of items can be coupled, such as materials, components, structures, layers, devices, objects, etc.

As used herein, “directly coupled” refers to a relationship of physical connection or attachment between one item and another item where the items have at least one point of direct physical contact or otherwise touch one another. For example, when one layer of material is deposited on or against another layer of material, the layers can be said to be directly coupled.

As used herein, “associated with” refers to a relationship between one item, property, or event and another item, property, or event. For example, such a relationship can be a relationship of communication. Additionally, such a relationship can be a relationship of coupling, including direct, indirect, electrical, or physical coupling. Furthermore, such a relationship can be a relationship of timing.

Objects or structures described herein as being “adjacent to” each other may be in physical contact with each other, in close proximity to each other, or in the same general region or area as each other, as appropriate for the context in which the phrase is used.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint. However, it is to be understood that even when the term “about” is used in the present specification in connection with a specific numerical value, that support for the exact numerical value recited apart from the “about” terminology is also provided.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 1.5, 2, 2.3, 3, 3.8, 4, 4.6, 5, and 5.1 individually.

This same principle applies to ranges reciting only one numerical value as a minimum or a maximum. Furthermore, such an interpretation should apply regardless of the breadth of the range or the characteristics being described.

Reference throughout this specification to “an example” means that a particular feature, structure, or characteristic described in connection with the example is included in at least one embodiment. Thus, appearances of the phrases “in an example” in various places throughout this specification are not necessarily all referring to the same embodiment.

### Example Embodiments

An initial overview of technology embodiments is provided below and specific technology embodiments are then described in further detail. This initial summary is intended to aid readers in understanding the technology more quickly, but is not intended to identify key or essential technological features, nor is it intended to limit the scope of the claimed subject matter.

Memory is one of the most dynamic input/output (I/O) interfaces in a computing device, catering to an ever-changing technological landscape ranging from high-performance devices such as computer servers to low-power devices such as handhelds. There is a high demand for robust memory technology to support speed, latency, and power consumption across all platforms. One avenue through which technological advances can be made to help fulfill such demand is by more efficient clock utilization strategies.

A clock generator produces a clock signal that oscillates between a high and a low state that is used to coordinate the timing of computational systems, devices, peripherals, circuits, and the like. One common clock signal is a square wave with a 50% duty cycle, often with a fixed and constant frequency. Circuits using the clock signal can trigger or become active on the rising edge, the falling edge, or both the rising and falling edges of the clock signal. In some cases, a clock signal can be gated by a control signal to alter the timing of the clock signal, to inactivate the clock signal during certain phases or periods, and the like.

DDR compliant memory is generally connected to a memory controller via a memory interface having various bus channels that transmit command and address signals (command/address or CA), clock signals, and data being read from or written to the DDR memory. The CA signal group contains command signals from the memory controller to the DDR-compliant memory providing read/write and other instructions, and address signals that provide the physical location of the requested read or write data. The CA signal group is synchronized to a clock, and at least any clock signal to which the CA can be synchronized is considered to be within the present scope. The clock can be the system clock, a memory controller clock, a distinct clock circuit, a data strobe, or the like. Any such clock shall be referred to collectively as the “clock”.

Memory subsystems as described herein may be compatible with a number of memory technologies, such as DDR (various specifications depending on DDR version, published by JEDEC), LPDDR (LOW POWER DOUBLE DATA RATE (LPDDR), various specifications depending on LPDDR version, published by JEDEC), WIO2 (Wide I/O 2 (WideIO2), JESD229-2, originally published by JEDEC in August 2014), HBM (HIGH BANDWIDTH MEMORY DRAM, JESD235, originally published by JEDEC in October 2013), HBM2 (HBM version 2, currently in discussion by JEDEC), and/or others, and technologies based on derivatives or extensions of such specifications. Additionally, unless noted otherwise, “DDR” refers to any implementation of DDR, such as DDR, DDR2, DDR3, DDR4, DDR5, and the like. DDR and DDRx can thus be used interchangeably. DDR specifications are overseen and published by JEDEC, including, for example, DDR4 (DDR version 4, initial specification published in September 2012 by JEDEC), DDR5 (DDR version 5, currently in discussion by JEDEC), and so on. LPDDR refers to any implementation of LPDDR, such as LPDDR1, LPDDR1E, LPDDR2, LPDDR2E, LPDDR3, LPDDR3E, LPDDR4, LPDDR4E, LPDDR5, LPDDR5E, and the like. LPDDR specifications are overseen and published by JEDEC, including, for example, LPDDR4 (LPDDR version 4, JESD209-4, originally published by JEDEC in August 2014), and (LPDDR version 5, currently in discussion by JEDEC),

CA signal groups of a DDRx memory channel can suffer from margin degradation in order to operate at the traditionally preferred 1N mode for higher speed bins. This happens primarily due to CA's need to support multi-loaded DRAM channels. On platforms with lower DDR speeds, this performance degradation was acceptable. However, with current memory speeds greater than 2400 megatransfers per second (MT/s), there appears to be no solution without sacrificing performance.

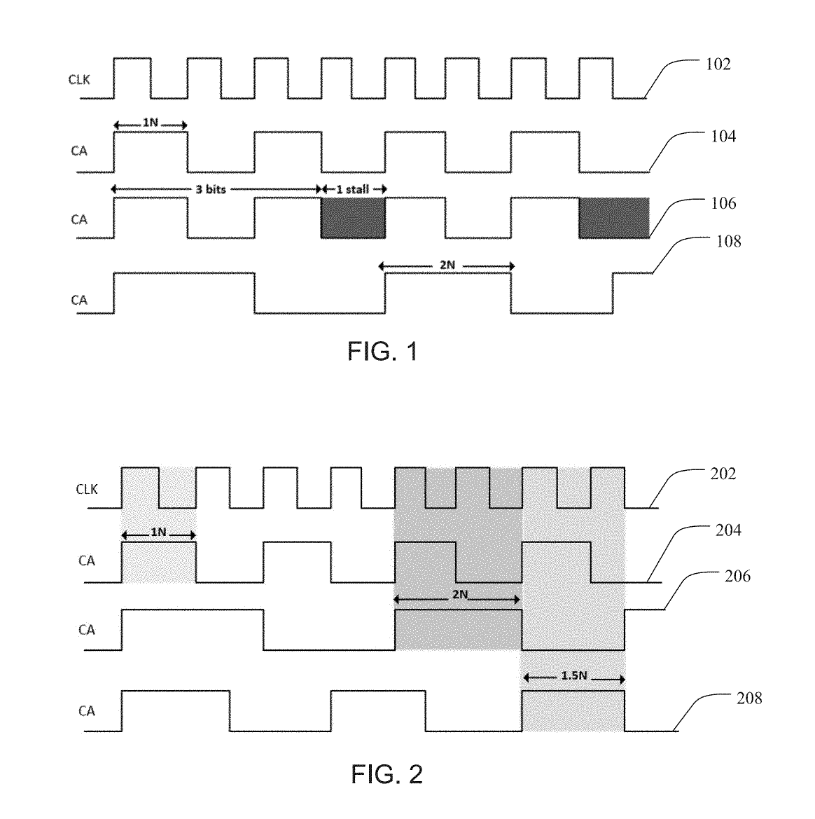

FIG. 1, for example, shows various synchronization timing schemes proposed as solutions to this problem. The clock signal 102 is shown for reference, along with the traditional CA timing scheme of 1N 104 (or 1.0 cycle timing), which is active for one full clock cycle at a 50% duty cycle. In order to avoid margin loss, a 3:1 bit scheme 106 can be used where three CA bits are latched in 1N mode with respect to clock frequency, while the fourth CA bit is “stalled.” The stalling of the fourth CA bit can be forced to a digital zero, one, or a tri-state. In another timing scheme, the CA bus is slowed down by half to a reduced-performance 2N timing 108 (or 2.0 cycle timing). The 2N timing works well at speeds higher than 1866 MT/s. However, for speeds greater than 2400 MT/s with heavy loading, neither of the above-recited options improve performance.

CA signal groups connect to multiple DRAM devices within the same channel, which forces CA to support a multitude of memory configurations with different loading across different platforms. This tends to cause common signal integrity issues, such as intersymbol interference (ISI), crosstalk, and the like, which results in margin degradation.

Various embodiments provide devices, systems, and associated methods that utilize a 1.5N scheme to increase the CA timing speed above 2N, while avoiding the margin degradation experienced at 1N timing. FIG. 2 shows that the fastest CA signal latching can be made by referencing to the differential clock signal 202 in one clock cycle, or 1N timing 204. Even though 1N timing adequately accommodates operation speed, the heavy loading induced lower margin negatively affects performance. Slowing the CA bus by half to 2N 206 reduces or eliminates the margin degradation experienced at 1N 202, but does so at the expense of CA throughput. As can be seen in FIG. 2, for the nearly eight clock signal 202 cycles, 1N timing 204 allows for four CA operations (eight if downticks are considered). 2N timing 206, on the other hand, allows for two CA operations (four with downticks). By contrast, 1.5N timing 208 (or 1.5 cycle timing) allows for three CA operations (six with downticks) in the same eight clock signal cycles while avoiding the margin degradation issues of the 1N timing scheme. The intermediate 1.5N timing mode takes advantage of available bandwidth of the CA signal group, and thus presents better performance while meeting various voltage and timing requirements.

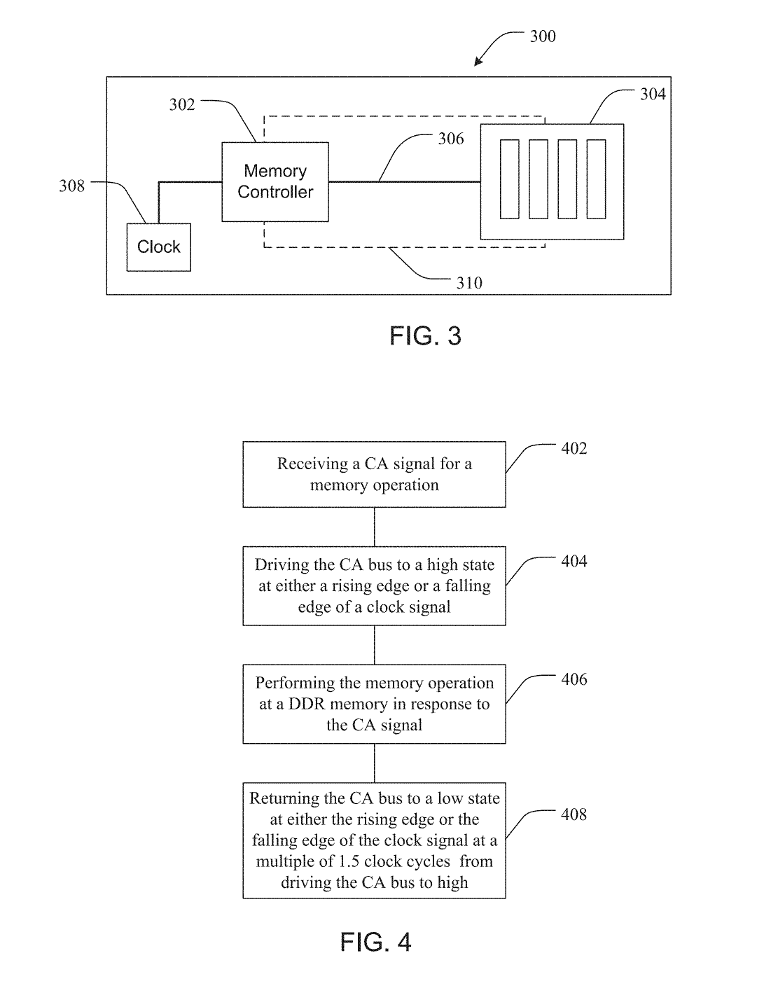

In one example, as shown in FIG. 3, a memory subsystem 300 having enhanced performance is provided comprising a memory controller 302, a DDR memory 304, and a memory bus 306 coupled to and providing communication between the memory controller 302 and the DDR memory 304. A clock signal source 308, such as a clock circuit, for example, is configured to generate a reference clock signal having a clock signal rate, and to provide the clock signal to the memory controller 302 and the DDR memory 304. While the clock signal source 308 is shown as a distinct component coupled to the memory controller 302 in FIG. 3, this is merely representative of the clock signal source component, and while this arrangement may be the case it should not be seen as limiting. For example, in some embodiments, the clock signal source 308 can be an integrated component of the memory controller 302. In other embodiments, the clock signal source 308 can be the system clock, and reside in a core of the CPU.

The memory bus 306 represents the various communication channels extending from the memory controller 302 to the DDR memory 304 and from the DDR memory 304 to the memory controller 302. The memory bus 306 can thus comprise one or more CA busses s, clock signals, data strobe and data signals, as well as any other bus or channel useful for communication between the memory controller 302 and the DDR memory 304.

The memory subsystem 300 can also comprise circuitry 310 configured to drive the CA bus of the memory bus 306 at a rate of 1.5 times the clock signal rate. The circuitry 310 is shown in FIG. 3 and is represented as a dashed box, which is drawn through the memory controller 302 and the DDR memory 304 to describe conceptually that the circuitry 310 can be realized throughout the memory subsystem 300, including the various components of the device.

Various embodiments provide circuitry designs capable of driving the memory bus and/or the CA bus at a rate of 1.5 times the clock signal rate. In one example embodiment, as is shown in FIG. 4, a method of increasing throughput of CA bus is provided that describes one example implementation of such circuit functionality. The method can include 402 receiving a CA signal for a memory operation at, for example, a memory controller, 404 driving the CA bus to a high state at either a rising edge or a falling edge of a clock signal, 406 performing the memory operation at a DDR memory in response to the CA signal, and 408 returning the CA bus to a low state at either the rising edge or the falling edge of the clock signal at a multiple of 1.5 clock cycles from driving the CA bus to high. In other words, upon receiving a CA signal, the CA bus is driven to a high state at either a rising edge of the clock signal or falling edge of clock signal. The CA bus is held in a high state for at least a 1.5 cycle duration, after which the CA bus returned to a low state, either at the rising edge or the falling edge of the clock signal. The duration can be any multiple of 1.5 cycles, such as 1.5, 3.0, 4.5, 6.0, and so on. Due to the multiples of 1.5 cycle durations, the CA bus can go low either on a rising edge or a falling edge depending on the duration that the CA bus was in the high state. For example, for a 1.5 cycle duration event, if the CA bus went high on the rising edge of the clock signal, it will go low on the falling edge of the clock signal after 1.5 cycles. As another example, for a 3.0 cycle duration event, if the CA bus went high on the rising edge of the clock signal, it will go low on the rising edge of the clock signal after 3.0 cycles. This high state represents an active duration of the command or instruction embedded in the CA signal to the DDR memory. Compared to the 1.0 cycle duration, the 1.5 cycle duration gives the signal half a clock cycle extra to, for example, meet the timing and voltage requirements so that the memory can read/latch the command (or bit).

In this context, performance can be driven by sending, for example, several commands that do not include data on the bus while the data bus is occupied with a command that does include data. As one example for 1N timing, each command is 1 clock cycle; however, a write command could also be accompanied by 4 clock cycles (or 8 bits) of data on the data bus leaving 3 dead clock cycles on the command bus. Thus by reducing the command timing speed, non-data commands can be sent along the CA bus without impacting, or by only minimally impacting, the data bus.

In one example, the CA signal can be a write instruction, and as such, the method can further comprise driving data from the memory controller to the DDR memory across the data bus in response to the CA signal, and writing the data to a memory location in the DDR memory. In another example, the CA signal can be a read instruction, and as such, the method can further comprise retrieving requested data from a memory location in the DDR memory and driving the requested data from the DDR memory to the memory controller across the data bus in response to the CA signal.

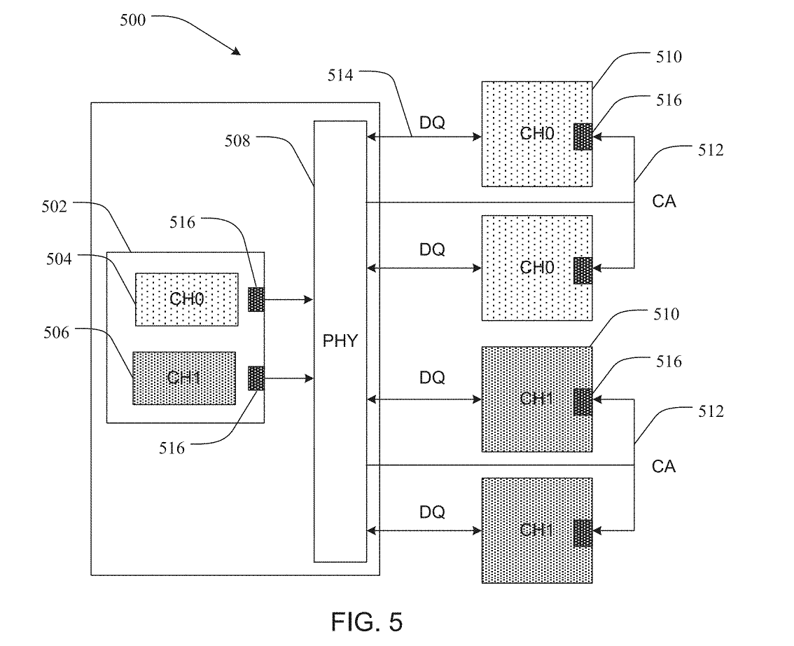

FIG. 5 shows an example of another memory subsystem 500 having improved CA bus bandwidth. The memory subsystem 500 shows an example having two memory channels, CH0 and CH1, although similar principles apply to devices having a single memory channel, as well as devices having more than two memory channels. The memory controller 502 can control the memory channels more or less independently as is shown in FIG. 5 using at least partially distinct processes, or the memory controller can control the memory channels from a single process. The memory controller 502 is shown having two controllers 504, 506, for controlling CH0 and CH1, respectively. The memory controller 502 controls DDR memory 510 in each of the two channels through the physical layer (PHY) 508. The device can further include a CA bus 512 coupling the DDR memory 510 to the memory controller 502 through the PHY layer 508. The CA bus 512 can control commands and addressing for one memory channel comprised of two DDR memory 510. Thus a memory channel device, as is shown in FIG. 5, will include two CA buses 512. The memory subsystem 500 can additionally include a DQ 514 for each DDR memory 510 in the device, which facilitates communication between the DDR memory 510 and the memory controller 502 through the PHY layer 508. It is noted that the number of DDR memory 510 can vary depending on the design of the system, and as such, the present scope can comprise any number of DDR memory units, irrespective of the number of channels, DRAM device densities, data bus widths, and the like.

In another example embodiment, the memory subsystem 500 can include 1.5N mode circuitry 516 configured to synchronize the CA bus 512, the memory controller 502, and the memory 510 to a 1.5N mode timing. The 1.5N mode circuitry 516 can be incorporated at any point in the circuitry of the device from the memory controller 502 through the DDR memory 510. In some cases, it can be beneficial to incorporate the 1.5N mode circuitry 516 into the memory controller 502 and the DDR memory 510. For example, circuitry at the memory controller end can be operable to drive command bits at multiples of 1.5 clock cycles. In some cases, circuitry can also be included that is operable to dynamically align 1N control bits. Circuitry at the DDR memory end can be operable to read on both rising and falling edges of the clock. Various circuit designs are contemplated, and multiple well-known conversion rate implementations can be utilized to drive the CA bus at 1.5 times the clock cycle and to read on both rising and falling edges, all of which are considered to be within the present scope. As one specific example, driving the data on the rising edge of a clock signal or on the falling edge of a clock signal can be accomplished by using a parallel in to serial out operation. One example of a circuit useful for such an operation comprises a multiplexer and a clock input to a select line of the multiplexer. Furthermore, various flip-flop type circuits can be implemented.

In one embodiment, for example, the 1.5N mode circuitry can process one or more command signals by inputting a plurality of incoming command signals into a buffer in a sequential order, and reading out the command signals one by one in a first in first out order at a delay of 1.5 clock signal cycles or a multiple of 1.5 clock cycles. By this, each command signal will drive the CA bus to a high state in the order in which it was received, held by a delay for some multiple of 1.5 cycles, after which the CA bus is returned to a low state, ready for the next command signal will be processed.

In another embodiment, circuitry can be implemented such that, with a control bit taking up 1 clock cycle for example, the memory controller could adjust which cycle it asserts the CA signal on within those encompassed by the command bit. The circuitry at the DDR end can read every clock edge, but only consider the bit accompanied by the appropriate CA signal.

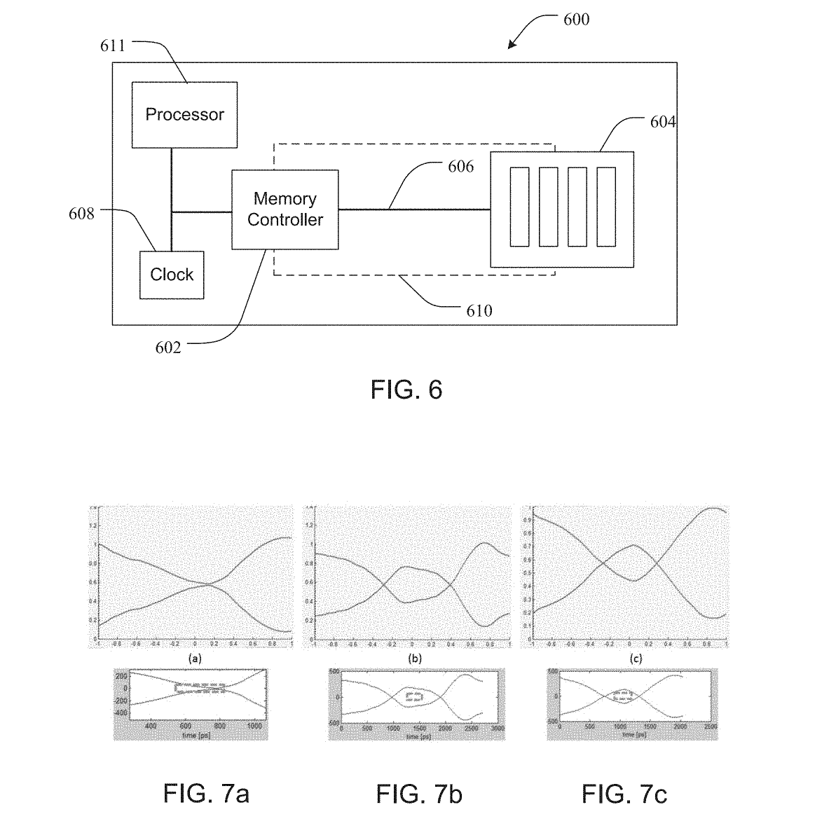

In another example, a computing system is provided having a memory subsystem synchronized to a clock signal at a 1.5N timing scheme. As is shown in FIG. 6, a computing system 600 can comprise a memory controller 602, a processor 611, a DDR memory 604, and a memory bus 606 coupled to and providing communication between the memory controller 602 and the DDR memory 604. A clock signal source 608, such as a clock circuit, is configured to generate a reference clock signal having a clock signal rate, and to provide the clock signal to the memory controller 602 and the DDR memory 604. While the clock signal source 608 is shown as a distinct component coupled to the memory controller 602 in FIG. 6, this is merely representative of the clock signal source component, and while this arrangement may be the case it should not be seen as limiting. For example, in some embodiments, the clock signal source 608 can be an integrated component of the memory controller 602. In other embodiments, the clock signal source 608 can be the system clock, and thus reside in a core of the processor 611.

The memory bus 606 represents the various communication channels extending from the memory controller 602 to the DDR memory 604, and from the DDR memory 604 to the memory controller 602. The memory bus 606 can thus comprise one or more CA busses, clock signals, data strobe and data signals, as well as any other bus or channel useful for communication between the memory controller 602 and the DDR memory 604.

The computing system 600 can also comprise circuitry 610 configured to drive the CA bus of the memory bus 606 at a rate of 1.5 times the clock signal rate. The circuitry 610 is shown in FIG. 6 and is represented as a dashed box, which is drawn through the memory controller 602 and the DDR memory 604 to describe conceptually that the circuitry 610 can be realized throughout the computing system 600, including the various components of the system.

Various embodiments of such systems can include laptop computers, handheld and tablet devices, CPU systems, SoC systems, server systems, networking systems, storage systems, high capacity memory systems, or any other computational system. Such systems can additionally include, in general, I/O interfaces for controlling the I/O functions of the system, as well as for I/O connectivity to devices outside of the system. A network interface can also be included for network connectivity, either as a separate interface or as part of the I/O interface. The network interface can control network communications both within the system and outside of the system. The network interface can include a wired interface, a wireless interface, a Bluetooth interface, optical interface, and the like, including appropriate combinations thereof. Furthermore, the system can additionally include various user interfaces, display devices, as well as various other components that would be beneficial for such a system.

The system can also include memory in addition to the described DDR memory that can include any device, combination of devices, circuitry, and the like that is capable of storing, accessing, organizing and/or retrieving data. Non-limiting examples include SANs (Storage Area Network), cloud storage networks, volatile or non-volatile RAM, phase change memory, optical media, hard-drive type media, and the like, including combinations thereof.

The processor 611 can be a single or multiple processors, and the memory can be a single or multiple memories. A local communication interface can be used as a pathway to facilitate communication between any of a single processor, multiple processors, a single memory, multiple memories, the various interfaces, and the like, in any useful combination.

The disclosed embodiments may be implemented, in some cases, in hardware, firmware, software, or any combination thereof. The disclosed embodiments may also be implemented as instructions carried by or stored on a transitory or non-transitory machine-readable (e.g., computer-readable) storage medium, which may be read and executed by one or more processors. A machine-readable storage medium may be embodied as any storage device, mechanism, or other physical structure for storing or transmitting information in a form readable by a machine (e.g., a volatile or non-volatile memory, a media disc, or other media device).

In one embodiment, reference to memory devices (or memory subsystems) can refer to nonvolatile memory device whose state is determinate even if power is interrupted to the device. In one embodiment, the nonvolatile memory device is a block addressable memory device, such as NAND or NOR technologies. Thus, a memory device can also include a future generation nonvolatile devices, such as a three dimensional crosspoint memory device, or other byte addressable nonvolatile memory device. In one embodiment, the memory device can be or include multi-threshold level NAND flash memory, NOR flash memory, single or multi-level Phase Change Memory (PCM), a resistive memory, nanowire memory, ferroelectric transistor random access memory (FeTRAM), magnetoresistive random access memory (MRAM) memory that incorporates memristor technology, or spin transfer torque (STT)-MRAM, or a combination of any of the above, or other memory.

In one example, as is shown in FIG. 7a-c, eye diagrams display simulation data obtained on a Kabylake®-Halo platform configured to support DDR4 in 1DPC at 2933 MT/s. FIG. 7a represents the eye diagram for CA in 1N mode. For a simple 1DPC case, the CA signal group has no margin, thereby warranting the need for 2N mode. Both eye diagram (top) and JEDEC mask (bottom) are shown in the figures. Note that the timing and voltage budgets for the CPU and DRAM allocated in the JEDEC mask (dashed box) remain the same across all of FIGS. 7a-c. The current mitigation option through 2N mode is shown in FIG. 7b with ample margin. The optimal channel utilization, however, is shown in FIG. 7c in a 1.5N configuration that not only meets the JEDEC mask criteria, but in addition enhances the performance through a faster latch.

### Examples

The following examples pertain to specific embodiments and point out specific features, elements, or steps that can be used or otherwise combined in achieving such embodiments.

In one example there is provided, a memory subsystem synchronized to a clock signal at a 1.5N timing scheme, comprising:

a memory controller;

a clock circuit configured to generate a reference clock signal having a clock signal rate;

a DDRx memory;

a command/address (CA) bus coupled to the memory controller and to the DDRx memory; and

circuitry configured to drive the CA bus at a rate of 1.5 times the clock signal rate.

In one example of a memory subsystem, wherein the circuitry further comprises a data bus coupled to the memory controller and to the DDRx memory.

In one example of a memory subsystem, the DDRx memory is DDR2 and above.

In one example of a memory subsystem, the DDRx memory is DDR4 and above.

In one example of a memory subsystem, the circuitry further comprises 1.5N mode circuitry configured to synchronize the CA bus, the memory controller, and the DDRx to a 1.5N mode timing.

In one example of a memory subsystem, the 1.5N mode circuitry is coupled to the memory controller and to the DDRx memory.

In one example of a memory subsystem, the 1.5N mode circuitry is further configured to:

drive data on a rising edge of the clock signal and on a falling edge of the clock signal; and

hold a command signal for 1.5 cycles of the clock signal.

In one example of a memory subsystem, driving the data on the rising edge of the clock signal or on the falling edge of the clock signal is by a parallel in to serial out operation.

In one example of a memory subsystem, in executing the parallel in to serial out operation, the 1.5N mode circuitry comprises a multiplexer and a clock input to a select line of the multiplexer.

In one example of a memory subsystem, in holding the command signal for 1.5 cycles, the 1.5N mode circuitry is further configured to:

input a plurality of incoming command signals into a buffer in a sequential order; and

read out a next command signal in a first in first out order from the plurality of incoming command signals at a delay of 1.5 clock signal cycles.

In one example of a memory subsystem, the device further comprises a physical interface functionally disposed between the memory controller and the DDRx memory.

In one example there is provided, a method of increasing throughput of a command/address (CA) bus, comprising:

receiving a CA signal at a memory controller;

latching the CA bus high at either a rising edge or a falling edge of a clock signal;

performing the CA signal instruction at a DDRx memory while the CA bus is latched high; and

unlatching the CA bus to low at either the rising edge or the falling edge of the clock signal at 1.5 cycles from latching.

In one example of a method of increasing throughput of a CA bus, the CA signal is a write instruction and the method further comprises;

driving data from the memory controller to the DDRx memory synchronized to rising edges and falling edges of the clock signal while the CA bus is latched high; and

writing the data to a memory location in the DDRx memory.

In one example of a method of increasing throughput of a CA bus, the CA signal is a read instruction and the method further comprises;

retrieving requested data from a memory location in the DDRx memory; and

driving the requested data from the DDRx memory to the memory controller synchronized to rising edges and falling edges of the clock signal while the CA bus is latched high.

In one example of a method of increasing throughput of a CA bus, latching and unlatching the CA bus further comprises:

latching the CA bus high at a rising edge of the clock signal; and

unlatching the CA bus to low at the falling edge of the clock signal at 1.5 cycles from latching.

In one example of a method of increasing throughput of a CA bus, latching and unlatching the CA bus further comprises:

latching the CA bus high at a falling edge of the clock signal; and

unlatching the CA bus to low at the rising edge of the clock signal at 1.5 cycles from latching.

In one example there is provided, a computing system having a memory subsystem synchronized to a clock signal at a 1.5N timing scheme, comprising:

a memory controller;

a processor;

a clock circuit configured to generate a reference clock signal having a clock signal rate;

a DDRx memory;

a command/address (CA) bus coupled to the memory controller and to the DDRx memory; and

circuitry configured to drive the CA bus at a rate of 1.5 times the clock signal rate.

In one example of a computing system, the circuitry further comprises a data bus coupled to the memory controller and to the DDRx memory.

In one example of a computing system, the circuitry further comprises 1.5N mode circuitry configured to synchronize the CA bus, the memory controller, and the DDRx to a 1.5N mode timing.

In one example of a computing system, the 1.5N mode circuitry is coupled to the memory controller and to the DDRx memory.

In one example of a computing system, the 1.5N mode circuitry is further configured to:

drive data on a rising edge of the clock signal and on a falling edge of the clock signal; and

hold a command signal for 1.5 cycles of the clock signal.

In one example of a computing system, driving the data on the rising edge of the clock signal or on the falling edge of the clock signal is by a parallel in to serial out operation.

In one example of a computing system, in executing the parallel in to serial out operation, the 1.5N mode circuitry comprises a multiplexer and a clock input to a select line of the multiplexer.

In one example of a computing system, in holding the command signal for 1.5 cycles, the 1.5N mode circuitry is further configured to:

input a plurality of incoming command signals into a buffer in a sequential order; and

read out a next command signal in a first in first out order from the plurality of incoming command signals at a delay of 1.5 clock signal cycles.

In one example of a computing system, the system further comprises a physical interface functionally disposed between the memory controller and the DDRx memory.

While the forgoing examples are illustrative of the principles of various embodiments in one or more particular applications, it will be apparent to those of ordinary skill in the art that numerous modifications in form, usage and details of implementation can be made without the exercise of inventive faculty, and without departing from the principles and concepts of the disclosure.

What is claimed is:

1. A memory subsystem comprising:
a DDRx memory;
a command/address (CA) interface coupled to the DDRx memory; and
circuitry configured to drive the CA interface at a rate of 1.5 times the clock signal rate of a reference clock signal.

2. The memory subsystem of claim 1, further comprising a memory controller, wherein the circuitry further comprises a data bus coupled to the memory controller and to the DDRx memory.

3. The memory subsystem of claim 1, wherein the DDRx memory is DDR2 and above.

4. The memory subsystem of claim 1, wherein the DDRx memory is DDR4 and above.

5. The memory subsystem of claim 1, further comprising a memory controller, wherein the circuitry further comprises 1.5N mode circuitry configured to synchronize the CA bus, the memory controller, and the DDRx to a 1.5N mode timing.

6. The memory subsystem of claim 5, wherein the 1.5N mode circuitry is coupled to the memory controller and to the DDRx memory.

7. The memory subsystem of claim 5, wherein the 1.5N mode circuitry is further configured to:
drive a command signal on a rising edge of the clock signal and on a falling edge of the clock signal; and
hold the command signal for a multiple of 1.5 cycles of the clock signal.

8. The memory subsystem of claim 7, wherein to drive the command signal on the rising edge of the clock signal and on the falling edge of the clock signal, the 1.5N mode circuitry uses a parallel in to serial out operation.

9. The memory subsystem of claim 8, wherein, for executing the parallel in to serial out operation, the 1.5N mode circuitry further comprises use of a multiplexer and a clock input to a select line of the multiplexer.

10. The memory subsystem of claim 1, wherein, the 1.5N mode circuitry is further configured to:
input a plurality of incoming command signals into a buffer in a sequential order; and
read out a next command signal in a first in first out order from the plurality of incoming command signals at a delay of a multiple of 1.5 clock signal cycles.

11. A method of increasing throughput of a command/address (CA) bus, comprising:
receiving a CA signal for a memory operation;
driving the CA bus to a high state at either a rising edge or a falling edge of a clock signal;
performing the memory operation at a DDRx memory in response to the CA signal; and
returning the CA bus to a low state at either the rising edge or the falling edge of the clock signal at a multiple of 1.5 clock cycles from driving the CA bus to high.

12. The method of claim 11, wherein the memory operation of the CA signal is a write instruction and the method further comprises:
driving data to the DDRx memory across a data bus in response to the CA signal; and
writing the data to a memory location in the DDRx memory.

13. The method of claim 11, wherein the memory operation of the CA signal is a read instruction and the method further comprises:
retrieving requested data from a memory location in the DDRx memory; and
driving the requested data from the DDRx memory across a data bus in response to the CA signal.

14. A computing system having a memory subsystem, comprising:
a DDRx memory;
a command/address (CA) interface coupled to the DDRx memory; and
circuitry configured to drive the CA interface at a rate of 1.5 times the clock signal rate of a reference clock signal.

15. The system of claim 14, further comprising a memory controller, wherein the circuitry further comprises a data bus coupled to the memory controller and to the DDRx memory.

16. The system of claim 14, further comprising a memory controller, wherein the circuitry further comprises 1.5N mode circuitry configured to synchronize the CA bus, the memory controller, and the DDRx to a 1.5N mode timing.

17. The system of claim 16, wherein the 1.5N mode circuitry is coupled to the memory controller and to the DDRx memory.

18. The system of claim 17, wherein the 1.5N mode circuitry is further configured to:
drive a command signal on a rising edge of the clock signal and on a falling edge of the clock signal; and
hold the command signal for a multiple of 1.5 cycles of the clock signal.

19. The system of claim 18, wherein to drive the command signal on the rising edge of the clock signal and on the falling edge of the clock signal, the 1.5N mode circuitry uses a parallel in to serial out operation.

20. The system of claim 19, wherein, for executing the parallel in to serial out operation, the 1.5N mode circuitry comprises a multiplexer and a clock input to a select line of the multiplexer.

21. The system of claim 18, wherein, the 1.5N mode circuitry is further configured to:
input a plurality of incoming command signals into a buffer in a sequential order; and
read out a next command signal in a first in first out order from the plurality of incoming command signals at a delay of a multiple of 1.5 clock signal cycles.

22. The system of claim 14, further comprising one or more of:
at least one processor communicatively coupled to the system;
a display communicatively coupled to the system;
a battery coupled to the system; or
a network interface communicatively coupled to the system.
